(19) United States
(12) Patent Application Publication
(10) Pub. No.: US 2025/0343539 A1
(43) Pub. Date: Nov. 6, 2025

(54) DIGITAL DISPLAY CONTROL BUFFER CIRCUIT AND DIGITAL DISPLAY CONTROL BUFFER APPARATUS

(71) Applicants: Analogix (Suzhou) Semiconductor Co., LTD., Suzhou (CN); ANALOGIX INTERNATIONAL LLC, Wilmington, DE (US)

(72) Inventors: Shi ZUO, Suzhou (CN); Liang XUE, Suzhou (CN); Zhongyuan HOU, Suzhou (CN)

(21) Appl. No.: 19/196,451

(22) Filed: May 1, 2025

Related U.S. Application Data
(63) Continuation of application No. PCT/CN2023/115979, filed on Aug. 30, 2023.

(30) Foreign Application Priority Data
Aug. 18, 2023 (CN) 202311049069.9

(51) Int. Cl. H03K 5/1252; G06F 3/14; H03K 3/037; H03K 17/687

(52) U.S. Cl. CPC H03K 5/1252; G06F 3/14; H03K 3/037; H03K 17/6871

(57) ABSTRACT

The present disclosure provides a digital display control buffer circuit and a digital display control buffer apparatus. The digital display control buffer circuit at least includes a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; the glitch removal circuit is used to output a control signal to the control end of the first switch device when a first signal outputted by the output end of the second comparison unit is a falling edge, such that the first switch device is turned off.

### CROSS-REFERENCE TO RELATED APPLICATIONS

The present disclosure is a continuation of PCT Application No. PCT/CN2023/115979 filed Aug. 30, 2023, which claims priority to Chinese Patent Application No. 2023110490699, filed on Aug. 18, 2023, and entitled “A DIGITAL DISPLAY CONTROL BUFFER CIRCUIT AND A DIGITAL DISPLAY CONTROL BUFFER APPARATUS”, the entire contents of which are incorporated herein by reference.

### TECHNICAL FIELD

The present disclosure relates to the field of communications, and in particular, to a digital display control buffer circuit and a digital display control buffer apparatus.

### BACKGROUND

A digital display control buffer (DDC buffer for short) is a buffer that enables communication between an upstream circuit and a downstream circuit in a repeater circuit that supports a wired multimedia communication protocol. The DDC buffer may monitor upstream and downstream signals, and respectively send the detected signals to the downstream and the upstream, to achieve communication between the upstream and the downstream. In addition, the DDC buffer may also isolate load capacitors of the upstream circuit and the downstream circuit. The DDC buffer achieves pull-up and pull-down functions of the level of an output signal by connecting a drain open N-type field effect transistor and a resistor in series, and such design can effectively achieve a 5V-voltage withstand function.

However, in a working mode in which the DDC buffer monitors an upstream signal and sends the signal to the downstream, a large glitch will be generated at a rising edge of the detected upstream signal, and the glitch will not only affect the duty ratio of the upstream signal, but also increase the risk of the upstream signal being mistakenly converted into a digital signal.

Therefore, there is an urgent need for a glitch removal circuit which can eliminate a glitch occurring during the digital display control buffer sending a signal from the upstream to the downstream.

### SUMMARY

According to one aspect of some embodiments of the present disclosure, provided is a digital display control buffer circuit, the digital display control buffer circuit at least including a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; a first input end of the glitch removal circuit is electrically connected to an output end of the first comparison unit, a second input end of the glitch removal circuit is electrically connected to an output end of the second comparison unit, and an output end of the glitch removal circuit is electrically connected to a control end of the first switch device, and the glitch removal circuit is used to output a control signal to the control end of the first switch device when a first signal outputted by the output end of the second comparison unit is a falling edge, such that the first switch device is turned off.

Optionally, the glitch removal circuit includes: a flip-flop unit, wherein a first input end of the flip-flop unit is the first input end of the glitch removal circuit, a second input end of the flip-flop unit is the second input end of the glitch removal circuit, an output end of the flip-flop unit is connected to a third input end of the flip-flop unit, and the flip-flop unit is used to perform triggering when the first signal is a falling edge and output a triggering signal; and a filtering unit, wherein a first input end of the filtering unit is electrically connected to the first input end of the flip-flop unit, a second input end of the filtering unit is connected to the output end of the flip-flop unit, an output end of the filtering unit is the output end of the glitch removal circuit, and the filtering unit is used to output the control signal when an edge of a second signal outputted by the first comparison unit is opposite to an edge of the triggering signal.

Optionally, wherein the flip-flop unit includes: a first D flip-flop, wherein the first D flip-flop is triggered by a falling edge, a reset pin of the first D flip-flop is the first input end of the flip-flop unit, a CLK pin of the first D flip-flop is the second input end of the flip-flop unit, a D pin of the first D flip-flop is the third input end of the flip-flop unit, and a Q pin of the first D flip-flop is the output end of the flip-flop unit.

Optionally, wherein the flip-flop unit includes an inverter and a second D flip-flop; wherein the second D flip-flop is triggered by a rising edge, an input end of the inverter is the second input end of the flip-flop unit, an output end of the inverter is electrically connected to a CLK pin of the second D flip-flop, a reset pin of the second D flip-flop is the first input end of the flip-flop unit, a D pin of the second D flip-flop is the third input end of the flip-flop unit, and a Q pin of the second D flip-flop is the output end of the flip-flop unit.

Optionally, the digital display control buffer circuit further includes: an operational amplifier, wherein the first comparison unit is a first comparator, the second comparison unit is a second comparator, the first switch device is a first NMOS transistor; an inverting input end of the first comparator is the first input end of the first comparison unit, an in-phase input end of the first comparator is a second input end of the first comparison unit and is used to input a first reference signal, and an output end of the first comparator is the output end of the first comparison unit; an inverting input end of the second comparator is the first input end of the second comparison unit, an in-phase input end of the second comparator is a second input end of the second comparison unit and is used to input a second reference signal, and an output end of the second comparator is the output end of the second comparison unit; and a gate of the first NMOS transistor is the control end of the first switch device, a drain of the first NMOS transistor is the first end of the first switch device, an inverting input end of the operational amplifier is respectively electrically connected to an output end of the operational amplifier and a source of the first NMOS transistor, the source of the first NMOS transistor is a second end of the first switch device, and an in-phase input end of the operational amplifier is used to input a third reference signal.

Optionally, the digital display control buffer circuit further includes: a second switch device, wherein a control end of the second switch device is electrically connected to the output end of the second comparison unit, a first end of the second switch device is electrically connected to the first end of the first comparison unit, and a second end of the second switch device is grounded.

Optionally, the second switch device is a second NMOS transistor, a gate of the second NMOS transistor is the control end of the second switch device, a drain of the second NMOS transistor is the first end of the second switch device, and a source of the second NMOS transistor is the second end of the second switch device.

Optionally, the digital display control buffer circuit further includes: a third comparator, wherein an inverting input end of the third comparator is used to input a fourth reference signal, an in-phase input end of the third comparator is used to input the upstream signal of the digital display control buffer circuit, and an output end of the third comparator is used to output a digital signal corresponding to the upstream signal.

According to another aspect of some embodiments of the present disclosure, provided is a digital display control buffer apparatus, including: any one of the digital display control buffer circuit.

Further, the digital display control buffer apparatus further includes: an upstream pull-down circuit, wherein the upstream pull-down circuit includes a first resistor, a second resistor and a third switch device, one end of the first resistor is used to connect to an upstream power supply end, an other end of the first resistor is respectively electrically connected to a first end of the third switch device and an end of the second resistor, the other end of the first resistor is used to input an upstream signal to the digital display control buffer circuit, and an other end of the second resistor and a second end of the third switch device are grounded; and a downstream pull-down circuit, wherein the downstream pull-down circuit includes a third resistor, a fourth resistor and a fourth switch device, one end of the third resistor is connected to a downstream power supply end, an other end of the third resistor is respectively electrically connected to an end of the fourth switch device and a first end of the fourth resistor, the other end of the third resistor is used to input a downstream signal to the digital display control buffer circuit, and an other end of the fourth resistor and a second end of the fourth switch device are grounded.

### BRIEF DESCRIPTION OF THE DRAWINGS

The drawings of the description, constituting a part of some embodiments of the present disclosure, are used for providing further understanding of some embodiments of the present disclosure, and the illustrative embodiments of some embodiments of the present disclosure and illustrations thereof are used to explain some embodiments of the present disclosure, rather than constitute inappropriate limitation on some embodiments of the present disclosure. In the drawings:

FIG. 1 shows a structural block diagram of a digital display control buffer circuit provided according to embodiments of the present disclosure;

FIG. 2 shows a structural block diagram of a glitch removal circuit provided according to embodiments of the present disclosure;

FIG. 3 shows a structural block diagram of a flip-flop unit provided according to embodiments of the present disclosure;

FIG. 4 shows a structural block diagram of another flip-flop unit provided according to embodiments of the present disclosure;

FIG. 5 shows a structural block diagram of another digital display control buffer circuit provided according to embodiments of the present disclosure;

FIG. 6 shows a schematic diagram of voltage change of an upstream signal;

FIG. 7 shows a schematic diagram of voltage change of an output signal of a second comparison unit, an output signal of a flip-flop unit, an output signal of a first comparison unit and a control signal which is outputted by a filtering unit provided according to embodiments of the present disclosure;

FIG. 8 shows a schematic diagram of voltage change of a signal provided according to embodiments of the present disclosure; and

FIG. 9 shows a structural block diagram of a digital display control buffer apparatus provided according to embodiments of the present disclosure.

The drawings include the following reference signs:
100: Digital display control buffer circuit; 101: Glitch removal circuit; 102: First comparison unit; 103: Second comparison unit; 104: First switch device; 105: Flip-flop unit; 106: Filtering unit; 107: First D flip-flop; 108: AND gate; 109: Second D flip-flop; 110: Inverter; 111: Operational amplifier; 112: Upstream pull-down circuit; 113: Downstream pull-down circuit.

### DETAILED DESCRIPTION OF THE EMBODIMENTS

It should be noted that the embodiments in the present disclosure and features in the embodiments can be combined with each other without conflicts. Hereinafter, the present disclosure is described in detail with reference to the accompanying drawings and in conjunction with the embodiments.

In order to make a person skilled in the art better understand the solutions of the present disclosure, hereinafter, the technical solutions in the embodiments of the present disclosure will be described clearly and thoroughly with reference to the accompanying drawings of embodiments of the present disclosure. Obviously, the embodiments as described are only some of the embodiments of the present disclosure, rather than all the embodiments. All other embodiments obtained by a person of ordinary skill in the art on the basis of the embodiments in the present disclosure without involving any inventive effort shall all fall within the scope of protection of the present disclosure.

It should be noted that the terms “first”, “second” etc., in the description, claims, and accompanying drawings of the present disclosure are used to distinguish similar objects, and are not necessarily used to describe a specific sequence or order. It should be understood that the data so used may be interchanged where appropriate, so that embodiments of the present disclosure described herein can be implemented in sequences other than those illustrated or described herein. In addition, the terms “include” and “have” and any variations thereof are intended to cover a non-exclusive inclusion, for example, a process, method, system, product or device that includes a series of steps or units is not necessarily limited to those steps or units that are clearly listed, but may include other steps or units that are not clearly listed or inherent to such process, method, product or device.

As introduced in the Background, in the related art, in the process of a digital display control buffer sending a signal from upstream to downstream, the delay of turning off an upstream switch device is long, and a glitch is generated. To solve the problems, embodiments of the present disclosure provide a digital display control buffer circuit and a digital display control buffer apparatus.

Hereinafter, the technical solutions in the embodiments of the present disclosure will be clearly and completely described in combination with the accompanying drawings in the embodiments of the present disclosure.

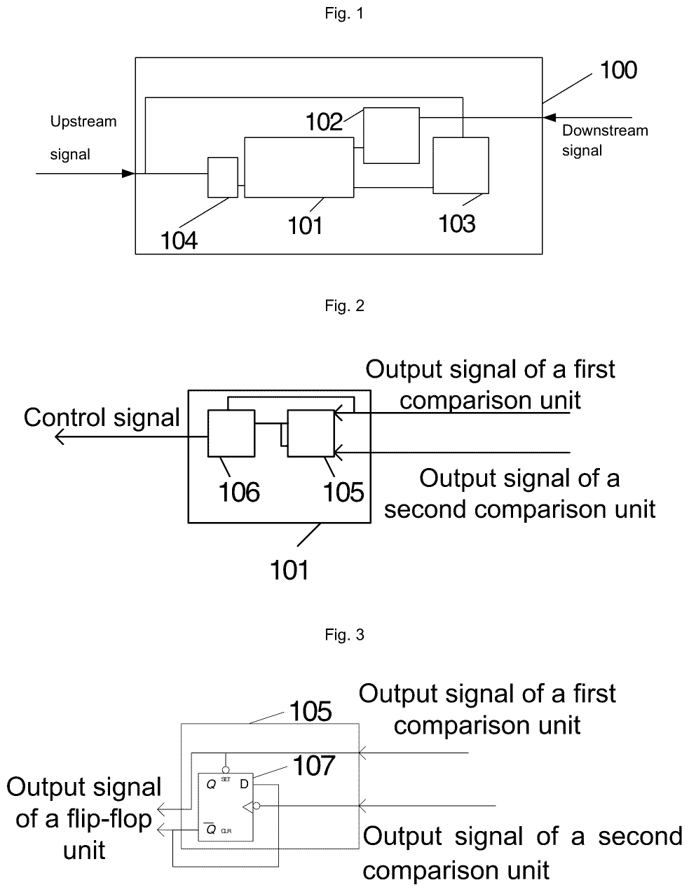

FIG. 1 is a structural block diagram of a digital display control buffer circuit provided according to embodiments of the present disclosure. As shown in FIG. 1, the digital display control buffer circuit 100 at least includes a glitch removal circuit 101, a first comparison unit 102, a second comparison unit 103 and a first switch device 104; a first end of the first switch device 104 and a first input end of the second comparison unit 103 are used to input an upstream signal of the digital display control buffer circuit 100, a first input end of the first comparison unit 102 is used to input a downstream signal of the digital display control buffer circuit 100; a first input end of the glitch removal circuit 101 is electrically connected to an output end of the first comparison unit 102, a second input end of the glitch removal circuit 101 is electrically connected to an output end of the second comparison unit 103, and an output end of the glitch removal circuit 101 is electrically connected to a control end of the first switch device 104; and the glitch removal circuit 101 is used to output a control signal to the control end of the first switch device 104 when a first signal outputted by the output end of the second comparison unit 103 is a falling edge, such that the first switch device 104 is turned off.

Specifically, the digital display control buffer circuit is a buffer circuit that enables communication between an upstream circuit and a downstream circuit in a repeater circuit that supports a wired multimedia communication protocol. The DDC buffer can monitor a signal of an upstream circuit and a signal of a downstream circuit, the signal of an upstream circuit is the upstream signal, the signal of a downstream circuit is the downstream signal, and respectively send the detected signals to the upstream circuit and the downstream circuit, thereby realizing the function of communication between the two. In actual applications, in a working mode in which the DDC buffer monitors an upstream circuit sending a signal to the downstream circuit, a transient overvoltage, i.e. a glitch, will be generated on a rising edge of the detected upstream signal. Although this glitch does not affect the function of the DDC buffer sending a signal to the downstream, it will affect the duty ratio of the upstream signal, and also increase the risk of the upstream signal being mistakenly converted into a digital signal. In fact, the glitch removal circuit performs triggering after directly acquiring a low-level control signal outputted by the second comparison unit, and outputs the control signal to directly control the first switch device, thereby greatly shortening the delay of turning off the first switch device, and further eliminating the glitch.

By the present embodiment, provided is a digital display control buffer circuit, the digital display control buffer circuit at least including a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; a first input end of the glitch removal circuit is electrically connected to an output end of the first comparison unit, a second input end of the glitch removal circuit is electrically connected to an output end of the second comparison unit, and an output end of the glitch removal circuit is electrically connected to a control end of the first switch device; and the glitch removal circuit is used to output a control signal to the control end of the first switch device when a first signal outputted by the output end of the second comparison unit is a falling edge, such that the first switch device is turned off. By introducing the glitch removal circuit in the digital display control buffer circuit, upon detection that upstream of the digital display control buffer sends a high-level signal, a low-level output signal of the downstream second comparison unit is received, and a control signal is outputted to the control end of the first switch device, such that the first switch device is turned off, which shortens the delay of turning off the first switch device, thereby preventing interruption of the process of rise of an upstream voltage, achieving the effect of removing a circuit glitch, and solving the problems of a long delay in turning off an upstream switch device and causing a glitch in the process of the digital display control buffer sending a signal from upstream to downstream.

In a specific implementation process, as shown in FIG. 2, the glitch removal circuit 101 includes: a flip-flop unit 105, wherein a first input end of the flip-flop unit 105 is the first input end of the glitch removal circuit 101, a second input end of the flip-flop unit 105 is the second input end of the glitch removal circuit 101, an output end of the flip-flop unit 105 is connected to a third input end of the flip-flop unit 105, and the flip-flop unit 105 is used to perform triggering when the first signal is a falling edge and output a triggering signal; and a filtering unit 106, wherein a first input end of the filtering unit 106 is electrically connected to the first input end of the flip-flop unit 105, a second input end of the filtering unit 106 is connected to the output end of the flip-flop unit 105, an output end of the filtering unit 106 is the output end of the glitch removal circuit 101, and the filtering unit 106 is used to output the control signal when the edge of a second signal outputted by the first comparison unit 102 is opposite to the edge of the triggering signal. For example, when the edge of a second signal outputted by the first comparison unit 102 is a rising edge, and the edge of the triggering signal is a falling edge, the filtering unit 106 is used to output the control signal. By implementing the glitch removal circuit through a combination of the flip-flop unit and the filtering unit, the glitch removal circuit can be further simplified.

Specifically, a flip-flop is an electronic element, is used for storing and stabilizing a signal, and an output state thereof can be changed under a specific input condition. The flip-flop is commonly used in digital circuits, and is used for storing and processing binary data. Various flip-flops have different input and output characteristics, and can be used to implement various logic functions and time sequence control. A person skilled in the art would have been able to select a corresponding flip-flop according to actual function requirements.

In order to further simplify the flip-flop unit, as shown in FIG. 3, the flip-flop unit 105 of the present disclosure includes: a first D flip-flop 107, wherein the first D flip-flop 107 is falling edge-triggered, a reset pin of the first D flip-flop 107 is the first input end of the flip-flop unit 105, a CLK pin of the first D flip-flop 107 is the second input end of the flip-flop unit 105, a D pin of the first D flip-flop 107 is the third input end of the flip-flop unit 105, and a Q pin of the first D flip-flop 107 is the output end of the flip-flop unit 105. Since the D flip-flop has characteristics of strong stability, high reliability, simple operation, wide applicability, strong programmability and high-speed performance, etc., by configuring the flip-flop unit as a D flip-flop, said circuit can further improve the effect of removing circuit glitches by the glitch removal circuit.

In particular, the D flip-flop is a basic digital logic circuit element, and is used for storing and transmitting information of a single bit. It has two input pins and two output pins, which are respectively a D input pin, a clock input pin, a Q output pin and a Q′ output pin. The D input pin is used to input data to be stored. When a clock signal arrives, the D flip-flop will store the value on the D input pin in an internal memory cell. The clock input pin is used to control an operation of the memory cell. When an edge of the clock signal arrives, the D flip-flop will update the state of the memory cell according to the value on the D input pin. The Q output pin is used to output the value stored in the memory cell. When an edge of the clock signal arrives, the value on the Q output pin will be updated to the value in the memory cell. The Q′ output pin is a complement of the Q output pin, that is, an opposite value of the Q output pin. When an edge of the clock signal arrives, the value on the Q′ output pin will be updated to an inverse value of the Q output pin. By controlling the value on the D input pin and the edge of the clock signal, different functions of the D flip-flop can be achieved, such as storage, transmission and timing control. The D flip-flop has high stability during operation, can resist the effects of noise and interference, and can ensure stable transmission and storage of data. Due to the storage characteristic of the D flip-flop, it can be ensured that data is reliably transmitted and stored under the action of the clock signal, and loss and errors of the data are effectively avoided. In addition, the D flip-flop has a high response speed and a high transmission rate, can meet the requirements of a high-speed timing sequence circuit, and is applicable to scenarios of high-speed data transmission and processing.

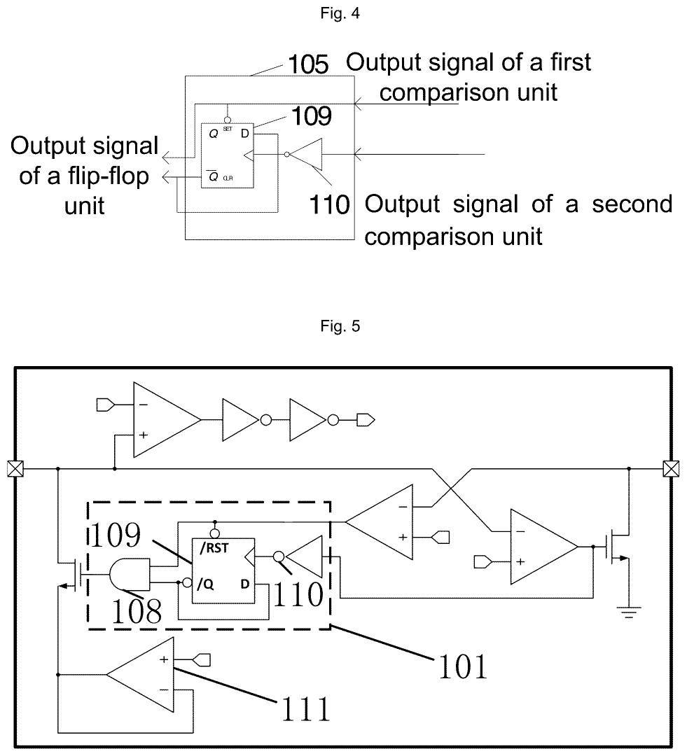

As shown in FIG. 4, the flip-flop unit 105 includes an inverter 110 and a second D flip-flop 109; wherein the second D flip-flop 109 is rising edge-triggered, an input end of the inverter 110 is the second input end of the flip-flop unit 105, an output end of the inverter 110 is electrically connected to a CLK pin of the second D flip-flop 109, a reset pin of the second D flip-flop 109 is the first input end of the flip-flop unit 105, a D pin of the second D flip-flop 109 is the third input end of the flip-flop unit 105, and a Q pin of the second D flip-flop 109 is the output end of the flip-flop unit 105. Since the D flip-flop has characteristics of strong stability, high reliability, simple operation, wide applicability, strong programmability and high-speed performance, etc., by configuring the flip-flop unit as a D flip-flop, said circuit can further improve the effect of removing circuit glitches by the glitch removal circuit.

Specifically, high-level triggering means that when the clock signal of the D flip-flop is at a high level, level change of a data input end may be read by the flip-flop; and low-level triggering means that when the clock signal of the D flip-flop is at a low level, level change of the data input end may be read by the flip-flop. In the high-level triggering mode, only when the clock signal is at a rising edge, can the change of the data input end be read by the flip-flop, and therefore only when the clock signal is at a rising edge, does output change occur. In the low-level triggering mode, only when the clock signal is at a falling edge, can the change of the data input end be read by the flip-flop.

In some embodiments, as shown in FIG. 5, the digital display control buffer circuit further includes: an operational amplifier 111, wherein the first comparison unit is a first comparator, the second comparison unit is a second comparator, the first switch device is a first NMOS transistor; an inverting input end of the first comparator is the first input end of the first comparison unit, an in-phase input end of the first comparator is a second input end of the first comparison unit and is used to input a first reference signal, and an output end of the first comparator is the output end of the first comparison unit; an inverting input end of the second comparator is the first input end of the second comparison unit, an in-phase input end of the second comparator is a second input end of the second comparison unit and is used to input a second reference signal, and an output end of the second comparator is the output end of the second comparison unit; and a gate of the first NMOS transistor is the control end of the first switch device, a drain of the first NMOS transistor is the first end of the first switch device, an inverting input end of the operational amplifier 111 is respectively electrically connected to an output end of the operational amplifier 111 and a source of the first NMOS transistor, the source of the first NMOS transistor is a second end of the first switch device, and an in-phase input end of the operational amplifier 111 is used to input a third reference signal. The configuration of the operational amplifier 111 can further ensure that the DDC buffer sends a low-voltage level signal to the upstream.

Specifically, the operational amplifier is used in the process of an upstream circuit sending a high-level signal, and at this time, the DDC buffer monitors upstream data and transmits the data to the downstream; as the first switch device and a second switch device are both turned on in the process of the upstream sending a low-level signal, at this time, the operational amplifier first pulls V_{SRC} from V_{SS} to V_{SRC_OL} by a constitution unit, i.e. a gain buffer. As shown in FIG. 5, the glitch removal circuit 101 consists of an AND gate 108, the second D flip-flop 109, and the inverter 110.

The digital display control buffer circuit of the present disclosure further includes: a second switch device, wherein a control end of the second switch device is electrically connected to the output end of the second comparison unit, a first end of the second switch device is electrically connected to the first end of the first comparison unit, and a second end of the second switch device is grounded. The second switch device is used to further control the downstream circuit.

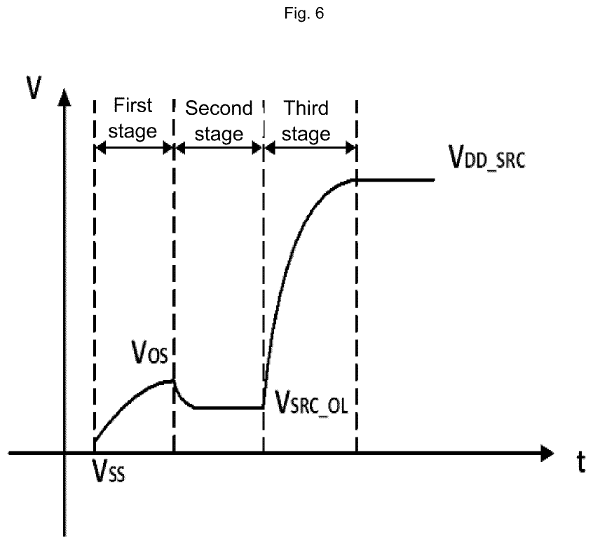

Specifically, as the third reference signal V_{OL_REF} is higher than the second reference signal V_{SNK_REF}, a negative-end input voltage of the second comparator is higher than a positive-end input voltage at this time, and the second switch device is turned off. A downstream end is not driven by the second switch device, and at this time, a negative input end of the first comparator is also higher than a positive input end, so that the first switch device is turned off, and a channel between V_{SRC} and V_{SRC_OL} is disconnected. That is to say, as shown in FIG. 6, when the DDC buffer monitors the high-level signal sent by an upstream end, the process of V_{SRC} rising to V_{DD_SRC} is divided into three stages: first, rising from V_{SS} to V_{SRC_OL}, then remaining for a period of time at the level V_{SRC_OL}, and finally rising to V_{DD_SRC}, wherein V_{OS} represents an overshoot voltage in the process that V_{SRC} is pulled to V_{SRC_OL} by the operational amplifier. The duration for which V_{SRC} remains at V_{SRC_OL} depends on the duration after the second switch device is turned off; and as a downstream load capacitor is large, said duration is long, and a glitch is also generated due to the existence of the overshoot voltage V_{OS} and the too long duration for which V_{SCR} remains at the level V_{SRC_OL}. In practice, the purpose of the glitch removal circuit is to shorten the time length of the second stage.

In some embodiments, the second switch device is a second NMOS transistor, a gate of the second NMOS transistor is the control end of the second switch device, a drain of the second NMOS transistor is the first end of the second switch device, and a source of the second NMOS transistor is the second end of the second switch device. Said circuit configures the second switch device as a second NMOS transistor, which can further simplify the second switch device and achieve control of a downstream signal by the second switch device.

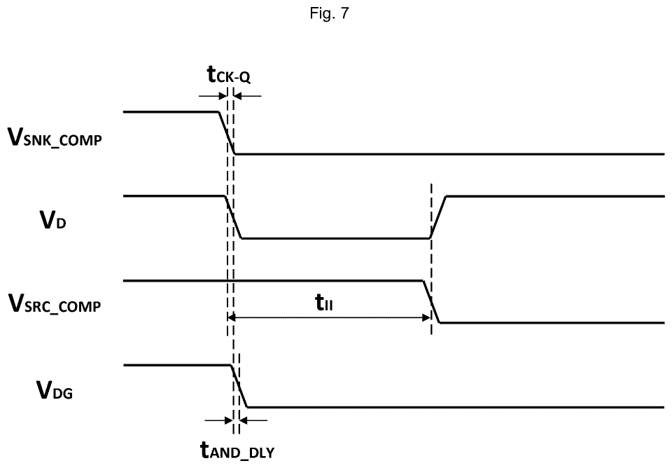

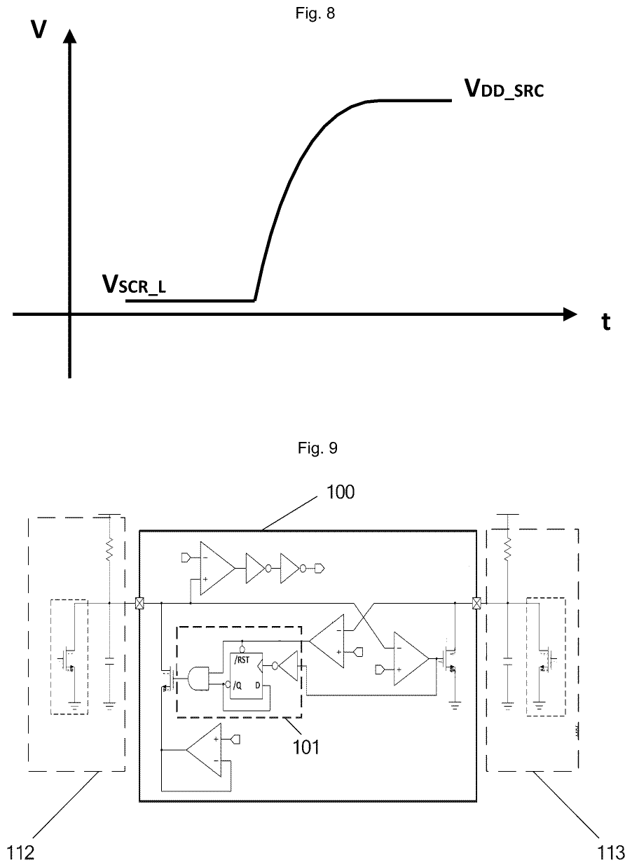

Specifically, when the upstream sends a high-level signal, the voltage change is as shown in FIG. 7, and in the process that V_{SRC} is pulled from V_{SS} to V_{SRC_OL}, the level of V_{SRC} is first higher than the second reference signal V_{SNK_REF} and the output signal V_{SNK_COMP} of the second comparator generates a falling edge; at this time, an output signal V_{SRC_COMP} of the first comparator is still high, the falling edge triggers a register, an output of an output signal V_{D} of the flip-flop unit is low after delay t_{CK-Q} of the flip-flop unit, and subsequently, the gate of the first switch device is pulled down after a delay t_{AND_DLY} of the filtering unit, and a channel between V_{SCR} and V_{SRC_OL} is disconnected. After the gate of the second switch device is pulled down by the output signal V_{SNK_COMP} of the second comparator, the level of the downstream signal V_{SNK} slowly rises; when V_{SNK} is higher than the first reference signal V_{SRC_REF}, the output signal V_{SRC_COMP} of the first comparator changes from high to low, the flip-flop in the flip-flop unit is reset, V_{D} is reset to be high, but an output signal V_{DG} of the filtering unit is still low, a pull-up process of the upstream signal V_{SRC}. is not interrupted, thereby completing a glitch removal process It should be noted that time t_{II} from the output signal V_{SNK_COMP} of the second comparator generating a falling edge to the output signal V_{SRC_COMP} of the first comparator jumping from high to low corresponds to the duration of the second stage in FIG. 6, and the first switch device is turned off by using the output signal V_{SNK_COMP} of the second comparator to trigger the flip-flop in the flip-flop unit; V_{SRC} rising to V_{SNK_REF} triggering the flip-flop to turning off the first switch device only requires a duration of delays of the flip-flop unit and the filtering unit (t_{CK-Q}+t_{AND_DLY}), which is far shorter than the time length t_{II} of the second stage in FIG. 6; and a rise waveform of V_{SRC} after glitch removal is as shown in FIG. 8.

The digital display control buffer circuit of the present disclosure further includes: a third comparator, wherein an inverting input end of the third comparator is used to input a fourth reference signal, an in-phase input end of the third comparator is used to input the upstream signal of the digital display control buffer circuit, and an output end of the third comparator is used to output a digital signal corresponding to the upstream signal. Said circuit can further generate a digital signal of the upstream signal.

In particular, the process of generating the digital signal by the comparator is as follows: determining ranges of input and output levels of the comparator, wherein the comparator generally has one or more input ends and one output end, the input ends receive analog signals, and the output end outputs a digital signal; and the ranges of the input and output levels are determined according to application requirements; a resistance voltage divider network or other circuits can be used to generate a reference level, an analog signal requiring to be converted into a digital signal is connected to the input end of the comparator, and the output end of the comparator is connected to a circuit requiring to receive the digital signal; according to practical requirements, a threshold of the comparator may need to be adjusted, so that a high level or a low level is outputted when an input signal exceeds or is lower than a certain level; and after the circuit is connected, the comparator is tested and verified, so as to ensure that the comparator can correctly convert the analog signal into a digital signal.

Embodiments of the present disclosure further provide a digital display control buffer apparatus, and the digital display control buffer apparatus provided in embodiments of the present disclosure will be introduced below.

The apparatus includes: any one of the digital display control buffer circuit above. The digital display control buffer circuit at least includes a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; a first input end of the glitch removal circuit is electrically connected to an output end of the first comparison unit, a second input end of the glitch removal circuit is electrically connected to an output end of the second comparison unit, and an output end of the glitch removal circuit is electrically connected to a control end of the first switch device; and the glitch removal circuit is used to output a control signal to the control end of the first switch device when a first signal outputted by the output end of the second comparison unit is a falling edge, such that the first switch device is turned off. The digital display control buffer circuit is a buffer circuit that enables communication between an upstream circuit and a downstream circuit in a repeater circuit that supports a wired multimedia communication protocol.

Specifically, the DDC buffer can monitor a signal of an upstream circuit and a signal of a downstream circuit, and respectively send the detected signals to the upstream circuit and the downstream circuit, thereby realizing the function of communication between the two. In actual applications, in a working mode in which the DDC buffer monitors an upstream circuit sending a signal to the downstream circuit, a transient overvoltage, i.e. a glitch, will be generated on a rising edge of the detected upstream signal. Although this glitch does not affect the function of the DDC buffer sending a signal to the downstream, it will affect the duty ratio of the upstream signal, and also increase the risk of the upstream signal being mistakenly converted into a digital signal. In fact, the glitch removal circuit performs triggering after directly acquiring a low-level control signal outputted by the second comparison unit, and outputs the control signal to directly control the first switch device, thereby greatly shortening the delay of turning off the first switch device, and further eliminating the glitch.

The present embodiment provides a digital display control buffer apparatus, the digital display control buffer apparatus includes a digital display control buffer circuit; the digital display control buffer circuit at least includes a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; a first input end of the glitch removal circuit is electrically connected to an output end of the first comparison unit, a second input end of the glitch removal circuit is electrically connected to an output end of the second comparison unit, and an output end of the glitch removal circuit is electrically connected to a control end of the first switch device; and the glitch removal circuit is used to output a control signal to the control end of the first switch device when a first signal outputted by the output end of the second comparison unit is a falling edge, such that the first switch device is turned off. By introducing the glitch removal circuit in the digital display control buffer circuit, upon detection that upstream of the digital display control buffer sends a high-level signal, a low-level output signal of the downstream second comparison unit is received, and a control signal is outputted to the control end of the first switch device, such that the first switch device is turned off, which shortens the delay of turning off the first switch device, thereby preventing interruption of the process of rise of an upstream voltage, achieving the effect of removing a circuit glitch, and solving the problems of a long delay in turning off an upstream switch device and causing a glitch in the process of the digital display control buffer sending a signal from upstream to downstream.

As an optional solution, as shown in FIG. 9, the digital display control buffer apparatus further includes: an upstream pull-down circuit 112, wherein the upstream pull-down circuit 112 includes a first resistor, a second resistor and a third switch device, one end of the first resistor is used to connect to an upstream power supply end, the other end of the first resistor is respectively electrically connected to a first end of the third switch device and a first end of the second resistor, the other end of the first resistor is used to input an upstream signal to the digital display control buffer circuit 100, and the other end of the second resistor and a second end of the third switch device are used to be grounded; and a downstream pull-down circuit 113, wherein the downstream pull-down circuit 113 includes a third resistor, a fourth resistor and a fourth switch device, one end of the third resistor is connected to a downstream power supply end, the other end of the third resistor is respectively electrically connected to a first end of the fourth switch device and a first end of the fourth resistor, the other end of the third resistor is used to input a downstream signal to the digital display control buffer circuit 100, and the other end of the fourth resistor and a second end of the fourth switch device are used to be grounded. The upstream pull-down circuit 112 may further adjust the upstream signal, and the downstream pull-down circuit 113 may further adjust the downstream signal.

Specifically, the digital display control buffer circuit further includes an upstream pull-down circuit and a downstream pull-down circuit, wherein the first resistor and the third resistor may be pull-up resistors, the second resistor and the fourth resistor may be load capacitors, and the third switch device and the fourth switch device may be NMOS transistors and are used to send data to the upstream circuit and the downstream circuit respectively.

It should also be noted that the terms “include”, “includes”, or any other variations thereof are intended to cover a non-exclusive inclusion, so that a process, method, commodity or device that includes a series of elements not only includes those elements, but also includes other elements that are not explicitly listed, or further includes inherent elements of the process, method, commodity, or device. Without further limitation, an element defined by a sentence “include a . . . ” does not exclude other same elements existing in the process, method, commodity, or device that includes the element.

From the description above, it can be determined that the embodiments of the present disclosure achieve the following technical effects:
1) The digital display control buffer circuit of the present disclosure at least includes a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; a first input end of the glitch removal circuit is electrically connected to an output end of the first comparison unit, a second input end of the glitch removal circuit is electrically connected to an output end of the second comparison unit, and an output end of the glitch removal circuit is electrically connected to a control end of the first switch device; and the glitch removal circuit is used to output a control signal to the control end of the first switch device when a first signal outputted by the output end of the second comparison unit is a falling edge, such that the first switch device is turned off. By introducing the glitch removal circuit in the digital display control buffer circuit, upon detection that upstream of the digital display control buffer sends a high-level signal, a low-level output signal of the downstream second comparison unit is received, and a control signal is outputted to the control end of the first switch device, such that the first switch device is turned off, which shortens the delay of turning off the first switch device, thereby preventing interruption of the process of rise of an upstream voltage, achieving the effect of removing a circuit glitch, and solving the problems of a long delay in turning off an upstream switch device and causing a glitch in the process of the digital display control buffer sending a signal from upstream to downstream.
2) The digital display control buffer apparatus of the present disclosure includes a digital display control buffer circuit, the digital display control buffer circuit at least includes a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; a first input end of the glitch removal circuit is electrically connected to an output end of the first comparison unit, a second input end of the glitch removal circuit is electrically connected to an output end of the second comparison unit, and an output end of the glitch removal circuit is electrically connected to a control end of the first switch device; and the glitch removal circuit is used to output a control signal to the control end of the first switch device when a first signal outputted by the output end of the second comparison unit is a falling edge, such that the first switch device is turned off. By introducing the glitch removal circuit in the digital display control buffer circuit, upon detection that upstream of the digital display control buffer sends a high-level signal, a low-level output signal of the downstream second comparison unit is received, and a control signal is outputted to the control end of the first switch device, such that the first switch device is turned off, which shortens the delay of turning off the first switch device, thereby preventing interruption of the process of rise of an upstream voltage, achieving the effect of removing a circuit glitch, and solving the problems of a long delay in turning off an upstream switch device and causing a glitch in the process of the digital display control buffer sending a signal from upstream to downstream.

The content above merely relates to preferred embodiments of the present disclosure and is not intended to limit some embodiments of the present disclosure. For a person skilled in the art, some embodiments of the present disclosure may have various modifications and variations. Any modifications, equivalent replacements, improvements, etc. made within the spirit and principle of some embodiments of the present disclosure shall all belong to the scope of protection of some embodiments of the present disclosure.

1. A digital display control buffer circuit, the digital display control buffer circuit at least comprising a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; a first input end of the glitch removal circuit is electrically connected to an output end of the first comparison unit, a second input end of the glitch removal circuit is electrically connected to an output end of the second comparison unit, and an output end of the glitch removal circuit is electrically connected to a control end of the first switch device, and the glitch removal circuit is used to output a control signal to the control end of the first switch device when a first signal outputted by the output end of the second comparison unit is a falling edge, such that the first switch device is turned off.

2. The digital display control buffer circuit according to claim 1, wherein the glitch removal circuit comprises:
a flip-flop unit, wherein a first input end of the flip-flop unit is the first input end of the glitch removal circuit, a second input end of the flip-flop unit is the second input end of the glitch removal circuit, an output end of the flip-flop unit is connected to a third input end of the flip-flop unit, and the flip-flop unit is used to perform triggering when the first signal is the falling edge and output a triggering signal; and
a filtering unit, wherein a first input end of the filtering unit is electrically connected to the first input end of the flip-flop unit, a second input end of the filtering unit is connected to the output end of the flip-flop unit, an output end of the filtering unit is the output end of the glitch removal circuit, and the filtering unit is used to output the control signal when an edge of a second signal outputted by the first comparison unit is opposite to an edge of the triggering signal.

3. The digital display control buffer circuit according to claim 2, wherein the flip-flop unit comprises: a first D flip-flop, wherein the first D flip-flop is triggered by a falling edge, a reset pin of the first D flip-flop is the first input end of the flip-flop unit, a CLK pin of the first D flip-flop is the second input end of the flip-flop unit, a D pin of the first D flip-flop is the third input end of the flip-flop unit, and a Q pin of the first D flip-flop is the output end of the flip-flop unit.

4. The digital display control buffer circuit according to claim 2, wherein the flip-flop unit comprises an inverter and a second D flip-flop; wherein the second D flip-flop is triggered by a rising edge, an input end of the inverter is the second input end of the flip-flop unit, an output end of the inverter is electrically connected to a CLK pin of the second D flip-flop, a reset pin of the second D flip-flop is the first input end of the flip-flop unit, a D pin of the second D flip-flop is the third input end of the flip-flop unit, and a Q pin of the second D flip-flop is the output end of the flip-flop unit.

5. The digital display control buffer circuit according to claim 1, wherein the digital display control buffer circuit further comprises: an operational amplifier, wherein the first comparison unit is a first comparator, the second comparison unit is a second comparator, the first switch device is a first N-Channel Metal Oxide Semiconductor (NMOS) transistor; an inverting input end of the first comparator is the first input end of the first comparison unit, an in-phase input end of the first comparator is a second input end of the first comparison unit and is used to input a first reference signal, and an output end of the first comparator is the output end of the first comparison unit; an inverting input end of the second comparator is the first input end of the second comparison unit, an in-phase input end of the second comparator is a second input end of the second comparison unit and is used to input a second reference signal, and an output end of the second comparator is the output end of the second comparison unit; and a gate of the first NMOS transistor is the control end of the first switch device, a drain of the first NMOS transistor is the first end of the first switch device, an inverting input end of the operational amplifier is respectively electrically connected to an output end of the operational amplifier and a source of the first NMOS transistor, the source of the first NMOS transistor is a second end of the first switch device, and an in-phase input end of the operational amplifier is used to input a third reference signal.

6. The digital display control buffer circuit according to claim 1, wherein the digital display control buffer circuit further comprises:
a second switch device, wherein a control end of the second switch device is electrically connected to the output end of the second comparison unit, a first end of the second switch device is electrically connected to the first end of the first comparison unit, and a second end of the second switch device is grounded.

7. The digital display control buffer circuit according to claim 6, wherein the second switch device is a second NMOS transistor, a gate of the second NMOS transistor is the control end of the second switch device, a drain of the second NMOS transistor is the first end of the second switch device, and a source of the second NMOS transistor is the second end of the second switch device.

8. The digital display control buffer circuit according to claim 1, wherein the digital display control buffer circuit further comprises:
a third comparator, wherein an inverting input end of the third comparator is used to input a fourth reference signal, an in-phase input end of the third comparator is used to input the upstream signal of the digital display control buffer circuit, and an output end of the third comparator is used to output a digital signal corresponding to the upstream signal.

9. A digital display control buffer apparatus, comprising a digital display control buffer circuit, the digital display control buffer circuit at least comprising a glitch removal circuit, a first comparison unit, a second comparison unit and a first switch device; a first end of the first switch device and a first input end of the second comparison unit are used to input an upstream signal of the digital display control buffer circuit, a first input end of the first comparison unit is used to input a downstream signal of the digital display control buffer circuit; a first input end of the glitch removal circuit is electrically connected to an output end of the first comparison unit, a second input end of the glitch removal circuit is electrically connected to an output end of the second comparison unit, and an output end of the glitch removal circuit is electrically connected to a control end of the first switch device, and the glitch removal circuit is used to output a control signal to the control end of the first switch device when a first signal outputted by the output end of the second comparison unit is a falling edge, such that the first switch device is turned off.

10. The digital display control buffer apparatus according to claim 9, wherein the digital display control buffer apparatus further comprises:
an upstream pull-down circuit, wherein the upstream pull-down circuit comprises a first resistor, a second resistor and a third switch device, one end of the first resistor is used to connect to an upstream power supply end, an other end of the first resistor is respectively electrically connected to a first end of the third switch device and an end of the second resistor, the other end of the first resistor is used to input an upstream signal to the digital display control buffer circuit, and an other end of the second resistor and a second end of the third switch device are grounded; and
a downstream pull-down circuit, wherein the downstream pull-down circuit comprises a third resistor, a fourth resistor and a fourth switch device, one end of the third resistor is connected to a downstream power supply end, an other end of the third resistor is respectively electrically connected to an end of the fourth switch device and a first end of the fourth resistor, the other end of the third resistor is used to input a downstream signal to the digital display control buffer circuit, and an other end of the fourth resistor and a second end of the fourth switch device are grounded.

11. The digital display control buffer apparatus according to claim 9, wherein the glitch removal circuit comprises:
a flip-flop unit, wherein a first input end of the flip-flop unit is the first input end of the glitch removal circuit, a second input end of the flip-flop unit is the second input end of the glitch removal circuit, an output end of the flip-flop unit is connected to a third input end of the flip-flop unit, and the flip-flop unit is used to perform triggering when the first signal is the falling edge and output a triggering signal; and
a filtering unit, wherein a first input end of the filtering unit is electrically connected to the first input end of the flip-flop unit, a second input end of the filtering unit is connected to the output end of the flip-flop unit, an output end of the filtering unit is the output end of the glitch removal circuit, and the filtering unit is used to output the control signal when an edge of a second signal outputted by the first comparison unit is opposite to an edge of the triggering signal.

12. The digital display control buffer apparatus according to claim 11, wherein the flip-flop unit comprises: a first D flip-flop, wherein the first D flip-flop is triggered by a falling edge, a reset pin of the first D flip-flop is the first input end of the flip-flop unit, a CLK pin of the first D flip-flop is the second input end of the flip-flop unit, a D pin of the first D flip-flop is the third input end of the flip-flop unit, and a Q pin of the first D flip-flop is the output end of the flip-flop unit.

13. The digital display control buffer apparatus according to claim 11, wherein the flip-flop unit comprises an inverter and a second D flip-flop; wherein the second D flip-flop is triggered by a rising edge, an input end of the inverter is the second input end of the flip-flop unit, an output end of the inverter is electrically connected to a CLK pin of the second D flip-flop, a reset pin of the second D flip-flop is the first input end of the flip-flop unit, a D pin of the second D flip-flop is the third input end of the flip-flop unit, and a Q pin of the second D flip-flop is the output end of the flip-flop unit.

14. The digital display control buffer apparatus according to claim 9, wherein the digital display control buffer circuit further comprises: an operational amplifier, wherein the first comparison unit is a first comparator, the second comparison unit is a second comparator, the first switch device is a first N-Channel Metal Oxide Semiconductor (NMOS) transistor; an inverting input end of the first comparator is the first input end of the first comparison unit, an in-phase input end of the first comparator is a second input end of the first comparison unit and is used to input a first reference signal, and an output end of the first comparator is the output end of the first comparison unit; an inverting input end of the second comparator is the first input end of the second comparison unit, an in-phase input end of the second comparator is a second input end of the second comparison unit and is used to input a second reference signal, and an output end of the second comparator is the output end of the second comparison unit; and a gate of the first NMOS transistor is the control end of the first switch device, a drain of the first NMOS transistor is the first end of the first switch device, an inverting input end of the operational amplifier is respectively electrically connected to an output end of the operational amplifier and a source of the first NMOS transistor, the source of the first NMOS transistor is a second end of the first switch device, and an in-phase input end of the operational amplifier is used to input a third reference signal.

15. The digital display control buffer apparatus according to claim 9, wherein the digital display control buffer circuit further comprises:
a second switch device, wherein a control end of the second switch device is electrically connected to the output end of the second comparison unit, a first end of the second switch device is electrically connected to the first end of the first comparison unit, and a second end of the second switch device is grounded.

16. The digital display control buffer apparatus according to claim 15, wherein the second switch device is a second NMOS transistor, a gate of the second NMOS transistor is the control end of the second switch device, a drain of the second NMOS transistor is the first end of the second switch device, and a source of the second NMOS transistor is the second end of the second switch device.

17. The digital display control buffer apparatus according to claim 9, wherein the digital display control buffer circuit further comprises:
a third comparator, wherein an inverting input end of the third comparator is used to input a fourth reference signal, an in-phase input end of the third comparator is used to input the upstream signal of the digital display control buffer circuit, and an output end of the third comparator is used to output a digital signal corresponding to the upstream signal.
